(19) United States
(12) Patent Application Publication
(10) Pub. No.: US 2016/0099724 A1
(43) Pub. Date: Apr. 7, 2016

(54) SYSTEM AND METHOD FOR IMPROVED UTF-8 ENCODING

(71) Applicant: Ivan Dossev, Pickering (CA)

(72) Inventor: Ivan Dossev, Pickering (CA)

(21) Appl. No.: 14/507,939

(22) Filed: Oct. 7, 2014

(51) Int. Cl. H03M 7/40

(52) U.S. Cl. CPC H03M 7/4093

(57) ABSTRACT

The present invention is directed to a method, system, and computer program for improved Unicode encoding (UTF-8C). Specifically, the use of a numeric offset system is employed to reduce coding complexity and to mitigate errors in decoding, as compared to standard UTF-8 encoding. Further, a non-zero null string filter may be used to improve the convenience of internalizing C-strings.

### BACKGROUND OF THE INVENTION

1. Field of the Invention

The present invention generally relates to a system and method for improved UTF-8 encoding. Specifically, the present invention employs a unique numeric offset scheme for encoding Unicode characters, which allows for overall reduced complexity and improved convenience.

2. Description of the Related Art

UTF-8 is a variable-width encoding scheme used to represent every character in Unicode, a character set for the representation and handling of text expressed in most of the world's writing systems. Since its creation, UTF-8 has become the dominant character encoding scheme for the World Wide Web. The World Wide Web Consortium (W3C) recommends UTF-8 as the default encoding in XML and HTML. UTF-8 has also increasingly been used as the default character encoding in many operating systems, programming languages, and software applications.

As a character encoding scheme, UTF-8 utilizes anywhere between one to four 8-bit bytes to encode each of the 1,112,064 valid code points in the known Unicode code space, as well as an additional 2,048 surrogate code points. The original design of UTF-8 is as follows, with the number of “x” bits denoting the payload values for mapping to various Unicode characters within specified ranges:

| | Range | Byte 1 | Byte 2 | Byte 3 | Byte 4 | Byte 5 | Byte 6 |
|---|---|---|---|---|---|---|---|
| 7 | U+0000-U+007F | 0xxxxxx | | | | | |
| 11 | U+0080-U+07FF | 110xxxxx | 10xxxxxx | | | | |
| 16 | U+0800-U+FFFF | 1110xxxx | 10xxxxxx | 10xxxxxx | | | |
| 21 | U+10000-U+1FFFFF | 11110xxx | 10xxxxxx | 10xxxxxx | 10xxxxxx | | |
| 26 | U+20000-U+3FFFFFF | 111110xx | 10xxxxxx | 10xxxxxx | 10xxxxxx | 10xxxxxx | |
| 31 | U+4000000-U+7FFFFFFF | 1111110x | 10xxxxxx | 10xxxxxx | 10xxxxxx | 10xxxxxx | 10xxxxxx |

There are several advantages to the original UTF-8 scheme shown above. First, the first byte of UTF-8 code is backwards compatible with ASCII values 0 through 127. Second, because the single bytes, leading bytes, and continuation bytes do not share values, the scheme is self-synchronizing, and allows the start of a character to be found by backing up at most five bytes. Third, there is a clear indication between multi-byte and single-byte sequences, as well as between continuation bytes and leading bytes. This is because the leading byte has two or more 1 bits followed by a 0 to denote the number of bytes in sequence, i.e., 110xxxx for a two byte sequence, 1110xxxx for a three byte sequence, and so forth.

However, the current UTF-8 scheme also comes with many disadvantages. For instance, a UTF-8 decoder has to reject overlong byte sequences, otherwise an attacker may be able to bypass certain security checks (e.g., check rejecting string containing null bytes, ex00). As an example, the bytes 0xC0 0x80 must raise an error in the decoder, otherwise it would be decoded as U+0000, Similarly, the character “.” (U+002E) might be encoded to 0xCO 0xAE to bypass directory traversal checks. Further, surrogate characters (U+D800-U+DFFF range), as well as ranges exceeding U+10FFFF also have to be rejected in order to conform to current design constraints. Thus, a second step must be programmed into a UTF-8 decoder to check for these range exceptions, in order to ensure that there is no corruption and to prevent system compromise from intentional hacks. This adds unnecessary complexity to the decoder.

Accordingly, the present invention contemplates an improved UTF-8 scheme that overcomes the disadvantages above, while maintaining key advantages of the original UTF-8 scheme previously discussed.

### SUMMARY OF THE INVENTION

The present invention (“UTF-8C”) is generally directed to a method, system, and computer program for improved UTF-8 encoding. Accordingly, it is an object of the present invention to increase the efficiency of the UTF-8 encoding scheme, to minimize the required UTF-8 decoder complexity, and to enhance overall security.

Specifically, key improvements of UTF-8C includes: solving over-long issues for continuation bytes; naturally bypassing illegal code points; natural final sequence for U+10FFFF; and improved convenience for C-strings. In addition, the original UTF-8 chassis is preserved and thus self-synchronization is maintained. Further, UTF-8C remains compatible with UTF-8 data in the 1^{st} and 2^{nd} byte ranges, which is sufficient for existing Western documents and code bases.

In initially broad terms, a method of the present invention utilizes a unique numeric offset scheme for encoding the Unicode code space to at least one byte or byte sequence. Accordingly, at least one Unicode character within the Unicode code space is encoded to at least one byte according to an encoding scheme. The at least one byte comprises an overhead portion and a payload portion. Generally speaking, the overhead portion serves as an index for a corresponding decoder to determine how many bytes are associated with the Unicode character to decode (length of the byte sequence), and what portion of those bytes comprise the payload portion that is to be decoded into a Unicode character.

Under the encoding scheme, a range of Unicode code space is represented by a given value range of the at least one byte, and a given offset is applied to the payload portion of the at least one byte based on the given range of the Unicode code space. Specifically, and in the preferred embodiment of the present invention, the Unicode range U+00..U+7F is represented with a first byte having a value range between 00..U7F, within this range, the value ED may be interpreted as U+00 in at least one embodiment. The Unicode range U+80..U+7FF is represented with the first byte and a second byte having respective value ranges of C2..DF and 80..BF, with a first offset applied to the payload portion. The Unicode range U+800..U+D7FF is represented by the first byte, the second byte, and a third byte having respective value ranges of E0..EC, 80..BF, and 80..BF, with a second offset applied to the payload portion. The Unicode range U+E000..U+FFFF is represented by the first byte, the second byte, and the third byte having respective value ranges of EE..EF, 80..BF, and 80..BF, with a third offset applied to the payload portion. Finally, the Unicode range U+10000.,U+10FFFF is represented by the first byte, the second byte, the third byte, and a fourth byte having respective value ranges of F0..F3, 80..BF, 80..BF, 80..BF, with a fourth offset applied to the payload portion.

The present invention may further comprise a decoding step or a corresponding decoder for decoding at least one byte to at least cne Unicode character in the Unicode code space. As such, the overhead portion of the at least one byte is first matched to determine the payload portion of the at least one byte, based on its initial bits. Next, the payload portion of the at least one byte is adjusted with a given offset in order to decode the at least one Unicode character. The offset may comprise a first, second, third, or fourth offset as described above and may be applied accordingly to the payload portion based on the overhead portion. In the preferred embodiment of the present invention, if the overhead portion of the first byte leads with 0, no offset is to be applied. However, the payload portion will be adjusted with a first offset, if the overhead portion of the first byte leads with the binary bit 110. The payload portion will be adjusted with a second offset, if the overhead portion of the first byte leads with binary bits 1110. The payload portion will be adjusted with a third offset, if the overhead portion of the first byte leads with the binary bits 1110111. Finally, the payload portion will be adjusted with a fourth offset, if the overhead portion of the first byte leads with the binary bits 111100.

Based on two exemplary implementations of the present invention, the first, second, third, and fourth offsets may comprise 0x00, 0x800, 0x00, and 0x10000 under the UTF-8C “Ant” method. In contrast, the first, second, third, and fourth offsets may comprise 0x3000, 0xDF800, 0xE0000, and 0x3BF0000 under the UTF-8C “Bee” method. These two methods employ different offsets values while maintaining the same encoding ranges described above for representing the Unicode code space with a byte sequence of one to four bytes. The differences are mainly a matter of coding system, although the “Bee” variation results in marginal performance increases due to lower code complexity.

Another feature of the present invention is directed to an addition to the encoding scheme, which comprises a particular representation of a null character. Specifically, the null character or U+00 may be represented with the hexadecimal value ED, which happens to be the one free gap to the UTF-8C encoding scheme.

This additional feature allows for improved convenience for receiving null terminated C-strings, as the value 0x00 can merely be filtered to 0xED. This offers a great improvement over existing modified UTF-8 (UTF-8M) which requires re-encoding the value to a two byte sequence. The “Ant” implementation of this feature would apply a trick offset to the payload portion of 0x00, provided the lead-byte mask nullifies the lead-byte. There are many payload mask and corresponding offset combinations that will satisfy the “Ant” implementation. The “Bee” implementation, on the other hand, would only ever apply a trick offset of 0xED. Of course, no offsets need to be applied as a decoder can also be hard-coded to interpret 0xED as U+00,

These and other objects, features and advantages of the present invention will become clearer when the drawings as well as the detailed description are taken into consideration.

### BRIEF DESCRIPTION OF THE DRAWINGS

For a fuller understanding of the nature of the present invention, reference should be had to the following detailed description taken in connection with the accompanying drawings in which:

FIG. 1 illustrates the encoding and decoding scheme of the current UTF-8 standard.

FIG. 2 illustrates the encoding and decoding scheme of an improved variation of UTF-8 according to one embodiment of the present invention, code named UTF-8C “Ant”.

FIG. 3 illustrates the encoding and decoding scheme of an improved variation of UTF-8 according to another embodiment of the present invention, code named UTF-8C “Bee”.

FIG. 4 is an example code implementation comparing the current UTF-8 standard with UTF-8C “Ant”.

FIG. 5 is an example code implementation comparing one embodiment of the present invention, the UTF-8C “Ant” implementation, with another embodiment of the present invention, UTF-8C “Bee”.

FIG. 6 is a flow chart directed to one embodiment of a method for improved Unicode encoding and decoding.

Like reference numerals refer to like parts throughout the several views of the drawings,

### DETAILED DESCRIPTION OF THE PREFERRED EMBODIMENT

As illustrated by the accompanying drawings, the present invention is directed to a method, system, and computer program for Unicode encoding, or UTF-8C. Specifically, the present invention cr UTF-8C is directed to improving and simplifying the existing UTF-8 encoding and decoding standard. In order to better understand how UTF-8C differs and improves upon the current standard, a brief background of the UTF-8 standard is first provided below.

For brevity and clarity,binary and hexadecimal representations in this document may be used interchangeably, and should not be construed to be limiting. For example, binary bits 11111111 may be illustrated as hexadecimal value FF, and vice versa. For purposes of brevity, the prefix 0x for hexadecimal representations may be omitted, i.e. 0xFF is equivalent to FF, In contrast, the prefix U+ is used exclusively to denote the Unicode code space throughout this document.

### The Current UTF-8 Standard

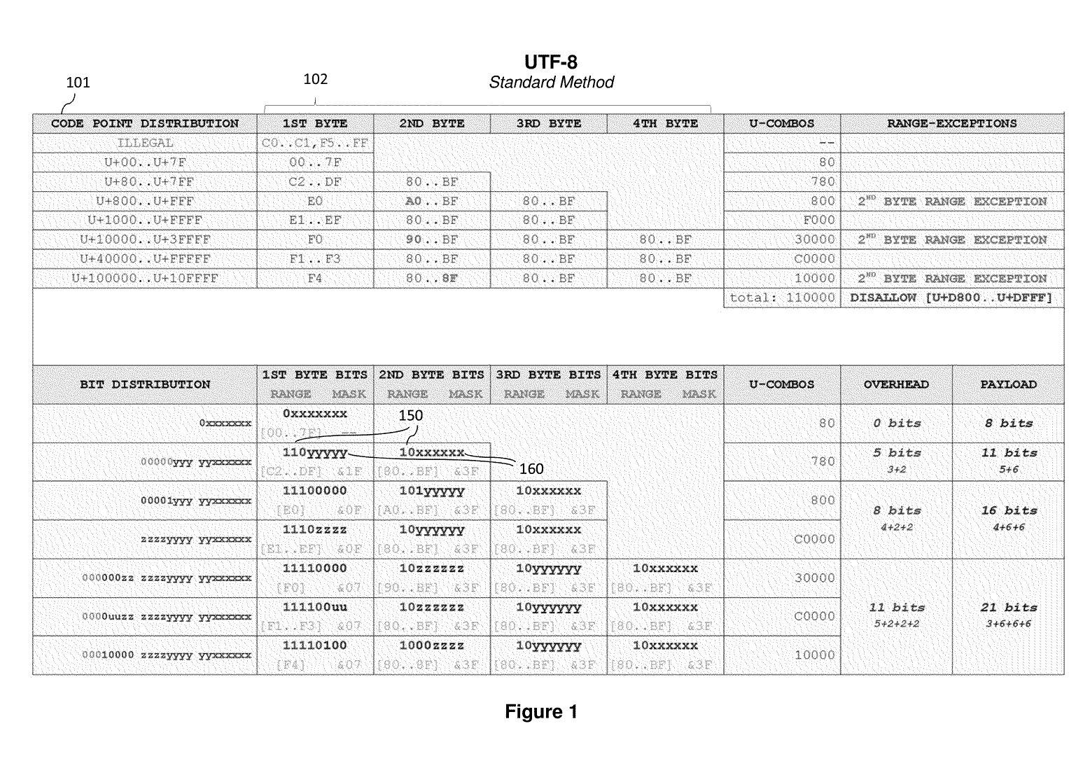

As illustrated in FIG. 1, the current UTF-8 method encodes the Unicode code space from U+00 .U+10FFFF, as in 101, to at least one byte or a byte sequence, as in 102, having various value ranges. For example, U+00..U+7F can be represented by only the first byte having a value range of 00..7F, while U+100000..U+10FFFF requires representation using a four byte sequence with the first byte having a value of F4, followed by 2^{nd} through 4^{th} bytes each having a value range between 80..8F, 80..BF, and 80..BF respectively.

The initial bits on each byte of the byte sequence, or the overhead portion as in 150, represents the Unicode range corresponding to the at least one byte. Based on the overhead portion, a corresponding decoder can first determine how many bytes correspond to the Unicode character to be decoded, or the length of the byte sequence, and what portion of each byte comprises the payload portion, as in 160, that is to be decoded

For example, if the first byte is 0xxxxxxx, the leading bit 0 is the overhead portion, and the remainder xxxxxxx is the payload portion. Accordingly, a corresponding decoder will then determine the number of bytes to be one, and then decode the payload portion cf that byte to resolve a Unicode character within the Unicode range U+00..U+7F. For example, 01111111 will decode to U+7F, 01000000 will decode to U+40, and 00000000 will decode to U+00.

Under the present UTF-8 standard, 7 different Unicode ranges (U+00..U+7F, U+80..U+7FF, U+800..U+FFF, 1.14-1000..U4TFFF, U+10000..U+3FFFF, U+40000..U+FFFFF, U+100000..U+10FFFF) require 7 different overhead representations on the at least one byte. Further, as another step and after decoding, the resulting Unicode code point must then be checked to ensure that it does not fall within an invalid range exception of U+D800.U+DFFF. This encoding scheme, however, presents an unnecessary level of complexity which requires additional special cases in writing a robust decoder, including checking for 2^{nd} continuation byte range exceptions. Incidentally, failure to account for any of these special cases may pose security risks, which is likely if the programmer is unaware cf these range exceptions or forgets to implement them.

Compared to the current standard implementation, the improved UTF-8C standard described below provides for a simpler solution that overcomes the disadvantages of UTF-8 described above,

### The Improved UTF-8C Standard

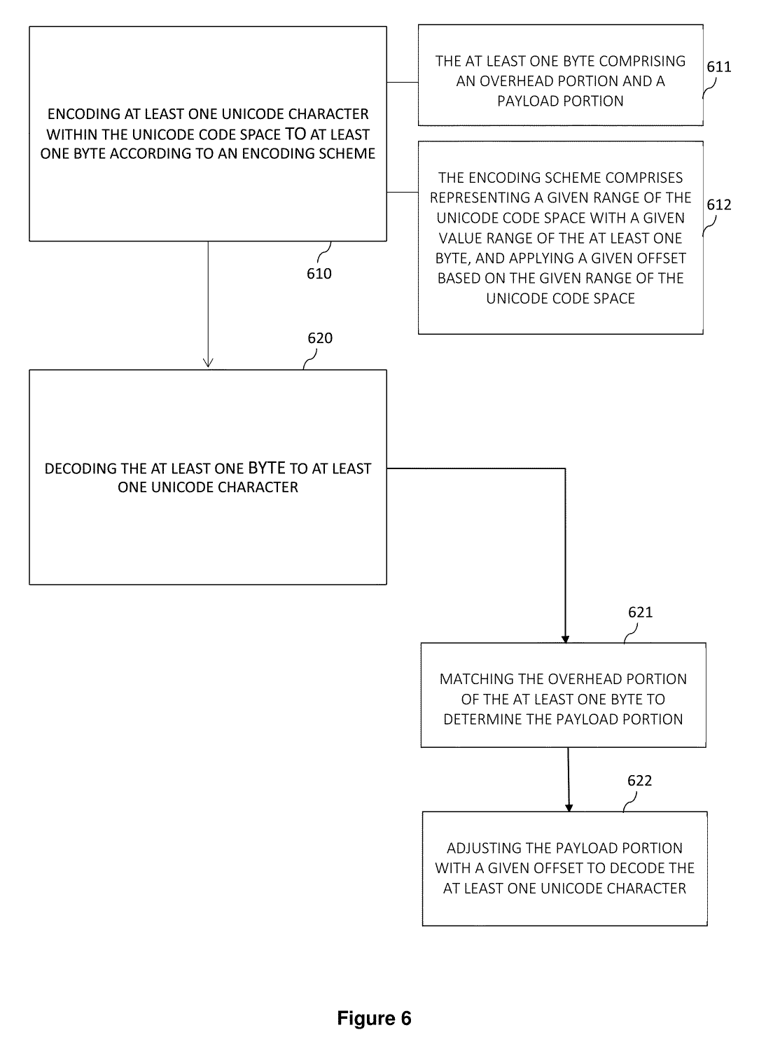

As discussed above, the present invention is directed to an improved UTF-8 encoding scheme, code named UTF-8C throughout this document which employs a unique numeric offset method. Accordingly, and as illustrated in FIG. 6, at least one Unicode character within the Unicode code space is first encoded to at least one byte according to an encoding scheme, as in 610.

The Unicode code space, as described above, has a hexadecimal range of U+00..U+10FFFF. The at least one byte, as in 611, comprises an overhead portion and a payload portion. As described above, the overhead portion serves as an index for the decoder to determine how many bytes are in the byte sequence associated with a Unicode character to decode, and what portion of those bytes are the payload portion to be decoded into a Unicode character.

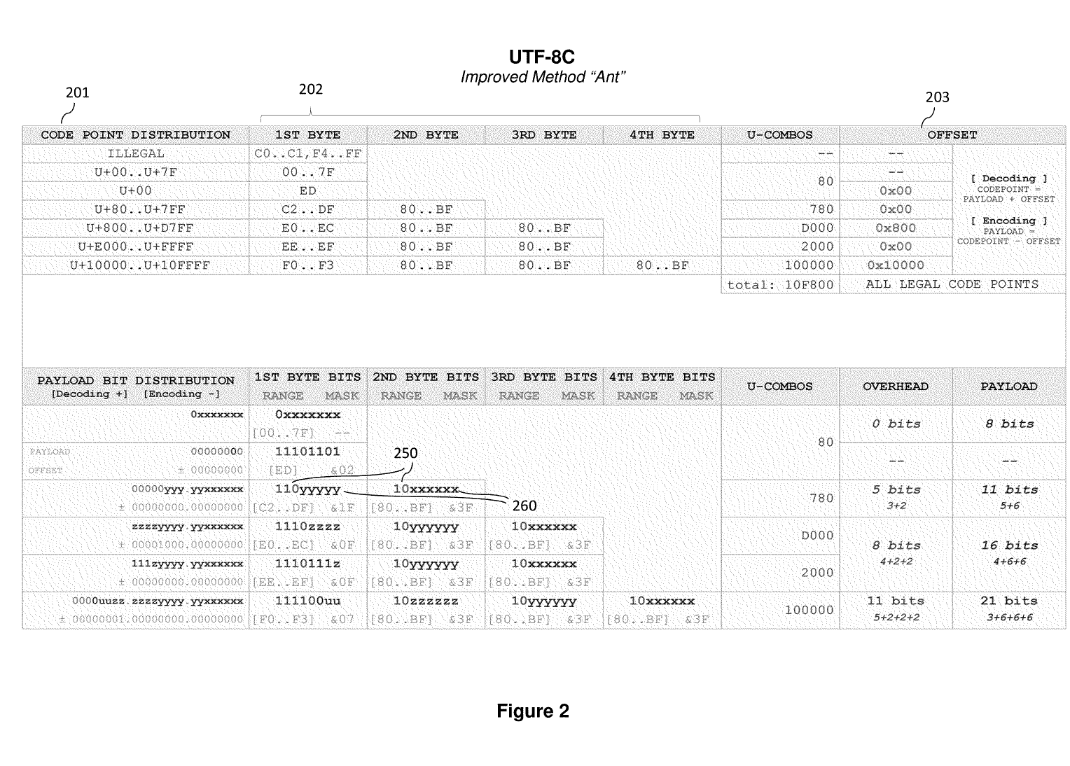

The encoding scheme, as in 612, comprises representing a given range of the Unicode code space with a given value range of the at least one byte, and applying a given offset to the payload portion of the at least one byte based on the given range of the Unicode code space. The given offset may comprise a positive or negative value. This encoding scheme or process can be better illustrated in FIG. 2, wherein different ranges of Unicode code space, as in 201, are uniquely mapped to different value ranges of the at least one byte 202 and have given offsets applied to the payload portion as in 203, based on the different ranges of the Unicode code space to be encoded.

For example, when encoding a code point in the Unicode code range 0+80..0+7FF, the range of values would be encoded to a first byte having a value range of C2..DF and a second byte having value range of 80..BF. An offset of 0x00, or no offset, would be applied to this range. As another example, if a code point in the Unicode code range U+800..U+D7FF was to be encoded to bytes 1, 2, 3, of E0..EC, 80..BF, 80..BF respectively, then an offset of 0x800 would be applied to the payload portions of the three bytes.

In a preferred embodiment of the present invention, particular different ranges of the Unicode code space are mapped to particular value ranges of up to four bytes. Specifically, the Unicode range 0+00..0+7F is represented with a first byte having a value range between 00..7F, however in at least one embodiment, U+00 may be separately represented by value ED. The Unicode range U+80..0+7FF is represented with the first byte and a second byte having respective value ranges of C2..DF and 80..BF, with a first offset applied to the payload portion. The Unicode range U+800..U+D7FF is represented by the first byte, the second byte, and a third byte having respective value ranges of E0..EC, 80..BF, and 80..BF, with a second offset applied to the payload portion. The Unicode range U+E000..U+FFFF is represented by the first byte, the second byte, and the third byte having respective value ranges of EE..EF, 80..BF, and 80..BF, with a third offset applied to the payload portion. Finally, the Unicode range 0+10000..U+10FFFF is represented by the first byte, the second byte, the third byte, and a fourth byte having respective value ranges of F0..F3, 80..BF, 80..BF, 80..BF, with a fourth offset applied to the payload portion,

The present invention may further comprise a decoding step, as in 620 of FIG. 6, in order to decode the at least one byte to at least one Unicode character in the Unicode code space. Accordingly, the overhead portion of the at least one byte is first matched, as in 621, to determine the payload portion of the at least one byte. Next, the payload portion of the at least one byte is adjusted, as in 622, with a given offset in order to decode the at least one Unicode character. The offset employed may match the encoding scheme described above and may comprise a positive or negative value. Thus, a first, second, third, or fourth offset as described above may be applied to the payload portion based on the overhead portion.

Specifically, and in accordance with FIG. 2, the adjusting step of the decoding method or a decoder will adjust the payload portion 260 of the byte sequence or at least one byte in accordance with its overhead bits 250. If the overhead portion of the first byte leads with 0, no offset is to be applied. However, the payload portion will be adjusted with a first offset, if the overhead portion of the first byte leads with the binary bit 110. The payload portion will be adjusted with a second offset, if the overhead portion of the first byte leads with binary bits 1110 The payload portion will be adjusted with a third offset, if the overhead portion of the first byte leads with the binary bits 1110111. Finally, the payload portion will, be adjusted with a fourth offset, if the overhead portion of the first byte leads with the binary bits 111100. The application of the encoder and adjustment of the decoder may comprise addition (+=) and subtraction (−=) operations.

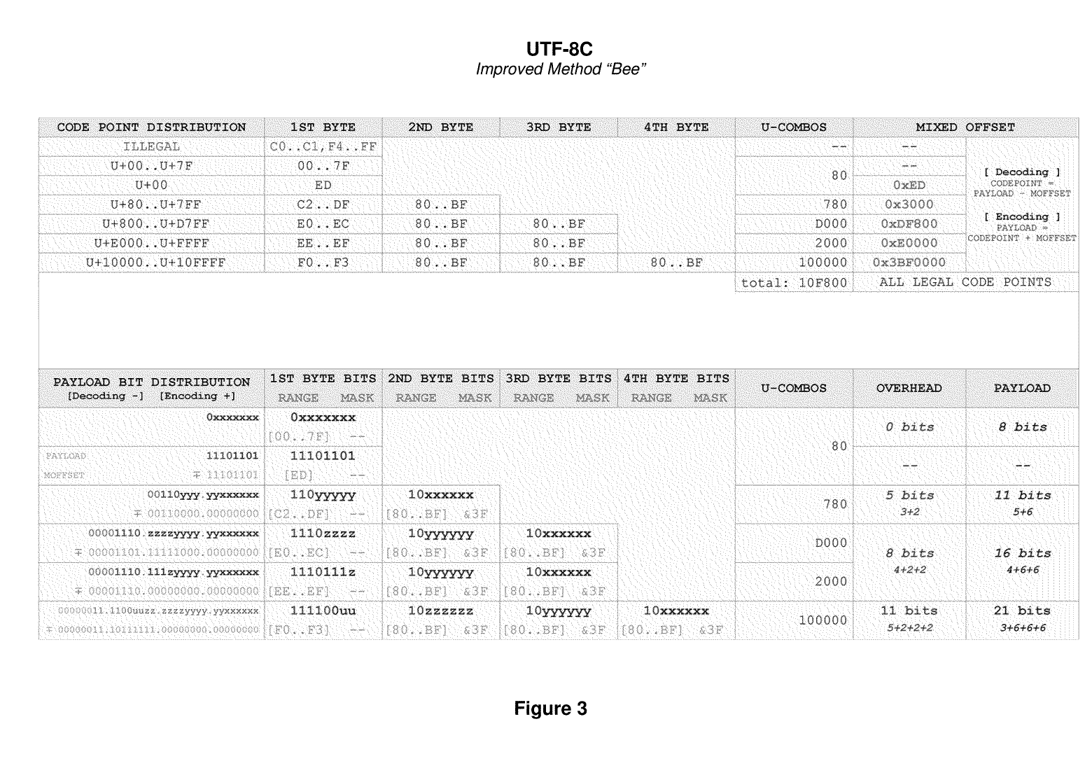

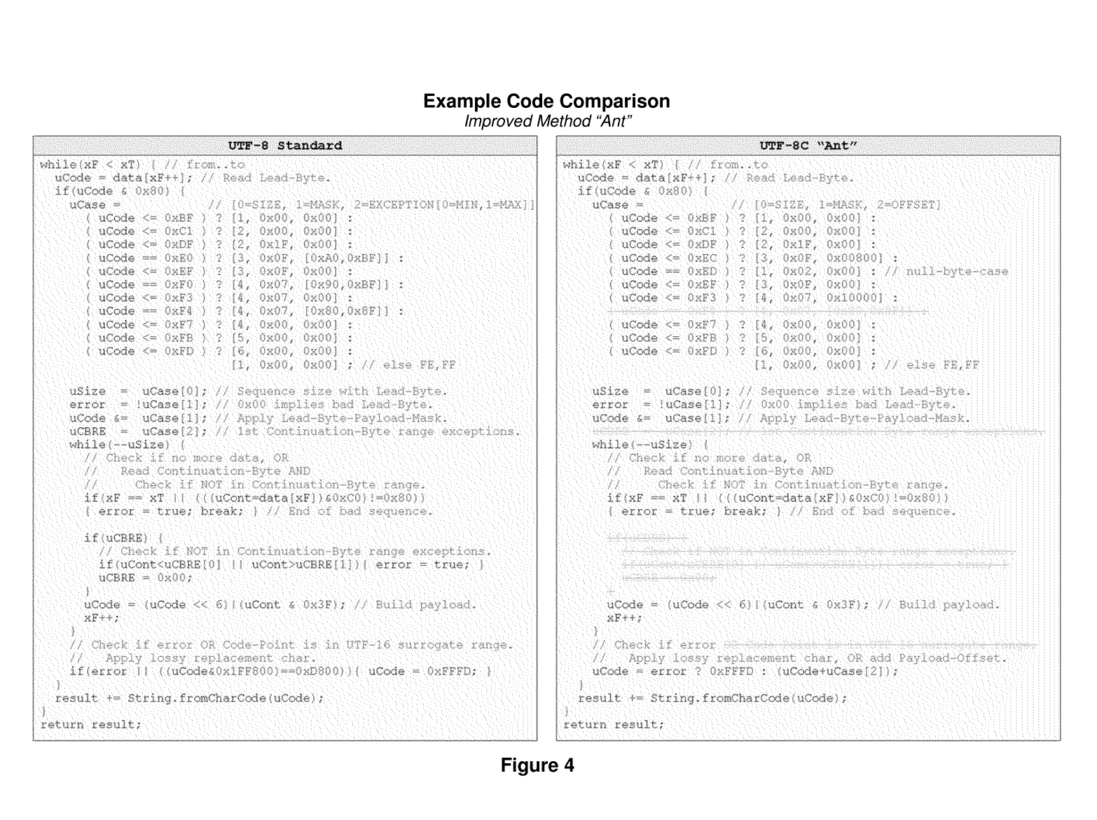

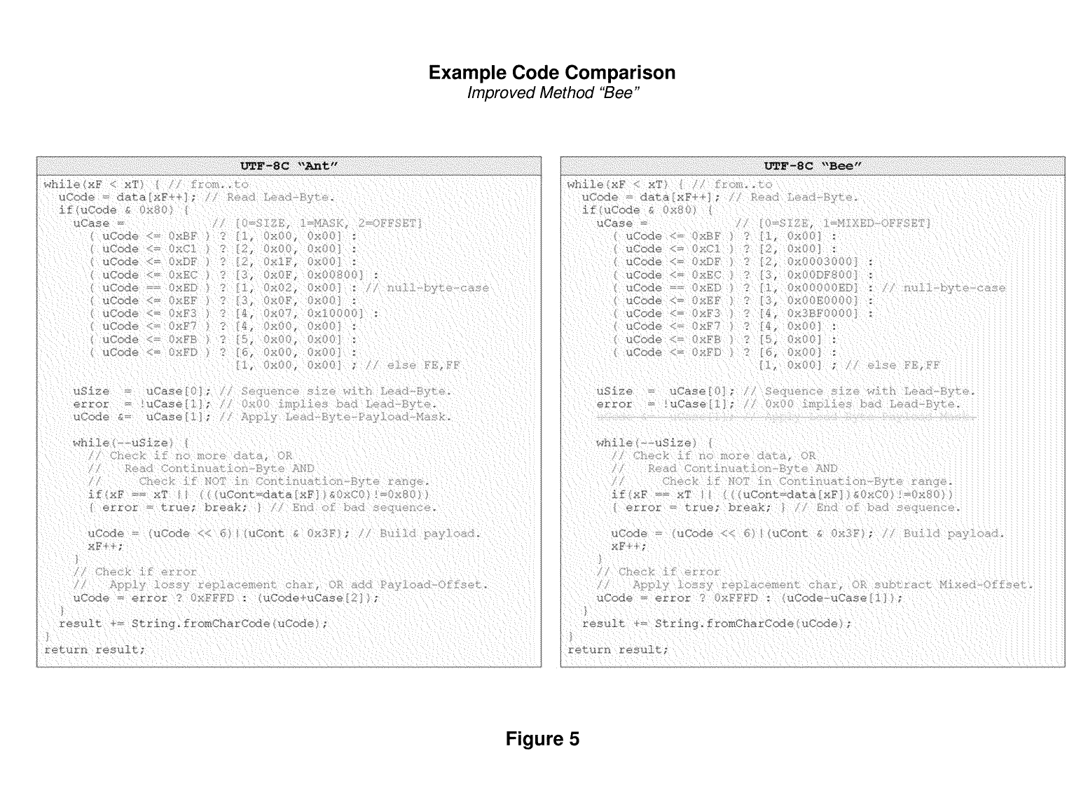

It should be understood that various different numeric offsets may be employed, as illustrated in FIGS. 2 and 4 showing the UTF-8C “Ant” method, versus the offset system illustrated in FIGS. 3 and 5 showing the UTF-8C “Bee” method. The example code segments presented are not intended to be limiting, as the present invention may be implemented in any number of programming languages known to a programmer skilled in the art, and the particular numeric offsets of the present invention may also be assigned and decoded using any base number numeral systems.

As such, the first, second, third, and fourth offsets described above may comprise different values while preserving the particular range allocation and representation of Unicode code space with one to four bytes as described above. Under the “Ant” embodiment, the first, second, third, and fourth offsets for the set ranges may comprise 0x 00, 0x800, 0x00, and 0x10000 respectively, in accordance with FIGS. 2 and 4 illustrating an example code implementation. Similarly, under the “Bee” embodiment, the first, second, third, and fourth offsets for the set ranges may comprise 0x3000, 0xDF800, 0xE0000, and 0x3BF0000 respectively, in accordance with FIGS. 3 and 5 illustrating another example code implementation. The “Bee” implementation combines the numeric payload offset of the “Ant” method with a lead byte overhead mask (post bit distribution) as one value. Thus, after the payload is calculated, the larger mixed offset is then subtracted, not added, to reveal the code point. The “Bee” implementation allows the code to omit traditional lead byte payload mask AND operation, and offers additional marginal performance gain due to a further reduction of code complexity.

In yet further embodiments of the present invention, the encoding scheme at 610 of FIG. 6 may further comprise the additional representation of a null character. Specifically, the null character, or U+00, may be represented with the hexadecimal value of ED, and applying a trick offset applied to the payload portion. In the “Ant” implementation of FIGS. 2 and 4, the trick offset may be omitted or may be 0x00, and any combination of payload mask and corresponding offset values may be used to satisfy this method. Further, the payload mask used in equating ED as null may serve as a trick value, if zeroed masks flag erroneous sequences in generic loop decoders. In the “Bee” implementation of FIGS. 3 and 5, the trick offset may simply be the value 0xED. The purpose of equating 0xED as 0x00 is for improved convenience for systems internalizing to C-strings, which allows for the faster processing of incoming data by merely filtering the value 0x00 to 0xED, rather than re-encoding it as a two byte sequence under a known method called UTF-8M. The value “ED” happened to be the one free gap in the UTF-8C design, and it is very convenient for the purpose of ending a string, i.e. think of “E” and “D” as “END”. Of course, no offsets need to be applied as a decoder can also be hard-coded to interpret 0xED as U+00.

It should also be understood that the above method may exist as other embodiments when not in operation. Specifically, a computer program may exist on a non-transitory storage medium such as a hard disk, flash drive, nonvolatile memory, or other storage device, which captures the operational processes and characteristics described above, and which may be executed by a computer or other device to perform the method described above. The computer program may be written in any language known to a person reasonably skilled in the art, such as C, C++, C#, Ruby, Java, Dart, Rust, Swift, and other equivalent languages and past, present and future variations.

Further, a physical system may also be designed by employing existing components and hardware known to those of ordinary skill in the art, such as to effect the operation of the method described above in a general purpose computer, a specialized computer or machine, as a system on chip, or as part of other integrated circuits or combination of circuitry and components.

Since many modifications, variations and changes in detail can be made to the described preferred embodiment of the invention, it is intended that all matters in the foregoing description and shown in the accompanying drawings be interpreted as illustrative and not in a limiting sense. Thus, the scope of the invention should be determined by the appended claims and their legal equivalents. Now that the invention has been described,

What is claimed is:

1. A method for Unicode encoding comprising:
encoding at least one Unicode character within the Unicode code space, having a hexadecimal range of U+00-10FEFF, to at least one byte according to an encoding scheme,
the at least one byte comprising an overhead portion and a payload portion,
the encoding scheme comprises representing a given range of the Unicode code space with a given value range of the at least one byte, and applying a given offset based on the given range of Unicode code space.

2. The method of claim 1 wherein the encoding scheme comprises:
representing U+00..01-7F with a first byte having a range between 00..7F,
representing U+80..U+7FF with said first byte having a range between C2..DF and a second byte having a range between 80..BF with a first offset applied to said payload portion,
representing U+800..U+D7FF with said first byte having a range between E0..EC, said second byte having a range between 80..BF, and a third byte having a range between 80..BF with a second offset applied to said payload portion,
representing U+E000..U+FFFF with said first byte having a range between EE..EF, said second byte having a range between 80..BF, and said third byte having a range between 80..BF with a third offset applied to said payload portion,
representing U+10000.U+10FFFF with said first byte having a range between F0..F3, said second byte having a range between 80..BF, said third byte having a range between 80..BF, and a fourth byte having a range between 80..BF with a fourth offset applied to said payload portion.

3. The method of claim 2 further comprising: decoding the at least one byte to a Unicode character, by:
matching the overhead portion of the first byte to determine the payload portion of the at least one byte,
adjusting the payload portion with the given offset to decode the Unicode character from the at least one byte.

4. The method of claim 3 wherein the adjusting steps further comprises:
adjusting the payload portion with a first offset, if the overhead portion of the first byte leads with binary bit 0,
adjusting the payload portion with second offset, if the overhead portion of the first byte leads with binary bits 110,
adjusting the payload portion with a third offset, if the overhead portion of the first byte leads with binary bits 1110,
adjusting the payload portion with a fourth offset, if the overhead portion of the first byte leads with binary bits 1110111,
adjusting the payload portion with a fifth offset, if the overhead portion of the first byte leads with binary bits 111100.

5. The method of claim 4 wherein the first offset is 0x00.

6. The method of claim 5 wherein the second offset is 0x800.

7. The method of claim 6 wherein the third offset is 0x00.

8. The method of claim 7 wherein the fourth offset is 0x10000.

9. The method of claim 4 wherein the first offset is 0x3000.

10. The method of claim 9 wherein the second offset is 0xDF800.

11. The method of claim 10 wherein the third offset is 0xE0000.

12. The method of claim 11 wherein the fourth offset is 0x3BF0000.

13. The method of claim 2 wherein the encoding scheme further comprises:
representing U+00 with the first byte having a hexadecimal value of “ED” with a trick offset applied to the payload portion.

14. The method of claim 13 further comprises:
decoding the at least one byte to the Unicode character U+00, by:
matching the overhead portion of the first byte to
determine the payload portion of the at least one byte,
adjusting the payload portion with a trick offset to decode the UA-00 from the at least one byte.

15. The method of claim 14 wherein the trick offset is 0x00.

16. The method of claim 15 wherein the trick offset is CxED.

17. The method of claim 2 wherein the encoding scheme further comprises:
representing U+00 with the first byte having a hexadecimal value of “ED”.

18. A computer program on a non-transitory computer readable medium, for execution by a computer for Unicode encoding, said computer program comprising:
an encoding code segment for encoding at least one Unicode character within the Unicode code space having a hexadecimal range of U+00..U+10FFFF, to at least one byte according to an encoding scheme,
said at least one byte comprising an overhead portion and a payload portion,
said encoding scheme comprising:
representing U+00..U+7F with a first byte having a range between 00..7F,
representing U+80..U+7FF with said first byte having a
range between C2..DF and a second byte having a range between 80..BF with a first offset applied to said payload portion,
representing U+800..U+D7FF with said first byte having a range between E0..EC, said second byte having a range between 80..BF, and a third byte having a range between 80..BF with a second offset applied to said payload portion,
representing U+E000..U+FFFF with said first byte having a range between EE..EF, said second byte having a range between 80..BF, and said third byte having a range between 80..BF with a third offset applied to said payload portion,
representing U+10000.0+10FFFF with said first byte having a range between F0..F3, said second byte having a range between 80..BF, said third byte having a range between 80..BF, and a fourth byte having a range between 80..BF with a fourth offset applied to said payload portion.

19. A system for Unicode encoding comprising:
an encoding module for encoding at least one Unicode character within the Unicode code space having a hexadecimal range of U+00..U+10FFFF, to at least one byte according to an encoding scheme,
said at least one byte comprising an overhead portion and a payload portion,
said encoding scheme comprising:
representing 13-1-00U IF with a first byte having a ranae
between 00..7F,
representing U +80 ...U+7FF with said first byte having a range between C2. DF and a second byte having a range between 80..BF with a first offset applied to said payload portion,
representing U+800..U+D7FF with said first byte having a range between E0..EC, said second byte having a range between 80..BF, and a third byte having a range between 80..3F with a second offset applied to said payload portion,
representing U+E000..U+FFFF with said first byte having a range between EE..EF, said second byte having a range between 80..BF, and said third byte having a range between 80..BF with a third offset applied to said payload portion,
representing U+10000. U+10FFFF with said first byte having a range between F0..F3, said second byte having a range between 80..BF, said third byte having a range between 80..BF, and a fourth byte having a range between 80..BF with a fourth offset applied to said payload portion.
